(19) United States
(12) Patent Application Publication
(10) Pub. No.: US 2026/0136689 A1
(43) Pub. Date: May 14, 2026

(54) IMAGERS FOR MID-WAVE INFRARED DETECTION

(71) Applicant: Raytheon Company, Tewksbury, MA (US)

(72) Inventors: Jose-Rodrigo Castillo-Garza, West Hartford, CT (US); Dong-Kyun Ko, Millburn, NJ (US)

(21) Appl. No.: 18/946,393

(22) Filed: Nov. 13, 2024

(51) Int. Cl. H01L 27/146

(52) U.S. Cl. CPC H10F 39/184

(57) ABSTRACT

An imaging device may include a substrate and a two-dimensional material (2DM) over the substrate. The 2DM may have a wide bandgap property, a first surface, a second surface, a first end, and a second end opposite the first end. The imaging device may also include a source electrode electrically coupled to the first end of the 2DM and a drain electrode electrically coupled to the second end of the 2DM. The imaging device may further include a first passivation layer over at least a portion of the 2DM, the source electrode, and the drain electrode. In addition, the photodetector may include a colloidal quantum-dot (CQD) film over the first passivation layer. The first passivation layer may electrically isolate the CQD film from the 2DM, the source electrode, and the drain electrode.

### TECHNICAL FIELD

This disclosure generally relates to electronic and optical devices. More specifically, this disclosure relates to imagers for mid-wave infrared detection.

### BACKGROUND

Mid-wave infrared (MWIR) imaging systems can, among other things, be used to capture thermal image details at distances of more than one kilometer. This is because MWIR atmospheric transmittance is larger than atmospheric transmittance in the electro-optical (EO), short-wave infrared (SWIR), and long-wave infrared (LWIR) bands. In some applications, MWIR imaging systems with sensitivities in the tens of milli-Kelvins are desired. Some MWIR imaging systems employ cryogenic cryocoolers to achieve the desired sensitivity. However, this increases the size, weight, power, and cost (SWAP-C) of the MWIR imaging system. This also increases the “time to system ready” of the MWIR imaging system since the system needs time to reach a suitable cryogenic temperature after power-up of the cryocooler, as well as increases the mean time between failures (MTBF), as the cryocooler must be periodically maintained.

### SUMMARY

This disclosure relates to imagers for mid-wave infrared detection.

In some examples, an imaging device may include a substrate, and at least one two-dimensional material (2DM) over the first passivation layer. The at least one 2DM may have a wide bandgap property, a first surface, a second surface, a first end, and a second end opposite the first end. The imaging device may also include a source electrode electrically coupled to the first end of the at least one 2DM and a drain electrode electrically coupled to the second end of the at least one 2DM. The imaging device may further include a first passivation layer over at least a portion of the at least one 2DM, the source electrode, and the drain electrode. In addition, the imaging device may include a colloidal quantum-dot (CQD) film over the first passivation layer. The first passivation layer may electrically isolate the CQD film from the at least one 2DM, the source electrode, and the drain electrode.

In other examples, a mid-wave infrared (MWIR) imaging system may include a substrate, a first passivation layer over at least a portion of the substrate, and a plurality of photodetectors over the substrate. Each photodetector may include at least one 2DM over the substrate, and the at least one 2DM may have a wide bandgap property, a first surface, a second surface, a first end, and a second end opposite the first end. The first passivation layer may isolate the substrate from the at least one 2DM. Each photodetector may also include a source electrode electrically coupled to the first end of the at least one 2DM and a drain electrode electrically coupled to the second end of the at least one 2DM. Each photodetector may further include a second passivation layer over at least a portion of the at least one 2DM, the source electrode, and the drain electrode. In addition, each photodetector may include a colloidal quantum-dot (CQD) film over the second passivation layer. The second passivation layer of each photodetector may electrically isolate the CQD film from the at least one 2DM, the source electrode, and the drain electrode.

In still other examples, a method may include selectively absorbing, via a CQD film of an MWIR imaging system, MWIR light. The method may also include measuring, between a source electrode and a drain electrode of the MWIR imaging system connected by a two-dimensional (2D) transport channel, a photocurrent induced onto the 2D transport channel by the absorbed MWIR light. The method may further include generating, by the MWIR imaging system, a thermal image based on the measured photocurrent. The 2D transport channel may include at least one 2DM having a wide bandgap property, a first surface, a second surface, a first end, and a second end opposite the first end. The source electrode may be electrically coupled to the first end of the at least one 2DM, and the drain electrode may be electrically coupled to the second end of the at least one 2DM. A first passivation layer may be over at least a portion of the at least one 2DM, the source electrode, and the drain electrode. The CQD film may be over the second passivation layer such that the second passivation layer can electrically isolate the CQD film from the at least one 2DM, the source electrode, and the drain electrode.

Any single one or any combination of the following features may be used with the above examples. The CQD film may be a mercury telluride (HgTe) CQD film. The HgTe CQD film may inherently possess an Auger suppression property. The HgTe CQD film may be Auger-suppressed. The HgTe CQD film may have a thickness of about 1 to 10 microns. The substrate may include at least one of a silicon (Si) backgate, a silicon dioxide (SiO₂) backgate, and a readout integrated circuit (ROIC). The 2DM may include at least one of molybdenum disulfide (MoS₂), molybdenum ditelluride (MoTe₂), and tungsten diselenide (WSe₂). The at least one 2DM may include a thin film of a single element having a thickness from 1 atom to 10 atoms of the element. At least one of the first passivation layer and the second passivation layer may include at least one of boron nitride (BN) 2DM, aluminum oxide (Al₂O₃), or titanium dioxide (TiO₂). There may be a second passivation layer over at least a portion of the substrate isolating the substrate from the at least one 2DM.

Other technical features may be readily apparent to one skilled in the art from the following figures, descriptions, and claims.

### BRIEF DESCRIPTION OF THE DRAWINGS

For a more complete understanding of this disclosure, reference is made to the following description, taken in conjunction with the accompanying drawings, in which:

FIGS. 1A and 1B illustrate an example photodetector in accordance with this disclosure;

FIGS. 2A and 2B illustrate operation of an example photodetector in accordance with this disclosure;

FIG. 3 illustrates an example mid-wave infrared (MWIR) imaging system in accordance with this disclosure; and

FIG. 4 illustrates an example method of operating an MWIR imaging system in accordance with this disclosure.

### DETAILED DESCRIPTION

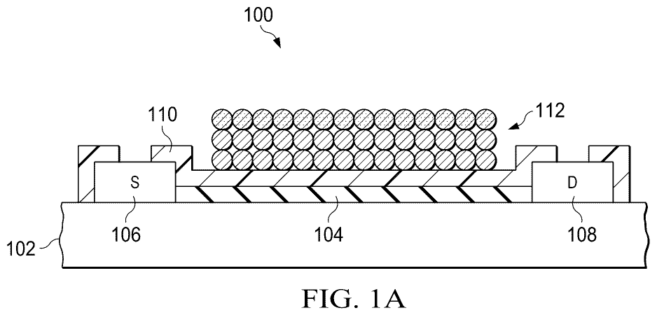

FIGS. 1A through 4, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, mid-wave infrared (MWIR) imaging systems can, among other things, be used to capture thermal image details at distances of more than one kilometer. This is because MWIR atmospheric transmittance is larger than atmospheric transmittance in the electro-optical (EO), short-wave infrared (SWIR), and long-wave infrared (LWIR) bands. In some applications, MWIR imaging systems with sensitivities in the tens of milli-Kelvins are desired. Some MWIR imaging systems employ cryogenic cryocoolers to achieve the desired sensitivity. However, this increases the size, weight, power, and cost (SWAP-C) of the MWIR imaging system. This also increases the “time to system ready” of the MWIR imaging system since the system needs time to reach a suitable cryogenic temperature after power-up of the cryocooler, as well as increases the mean time between failures (MTBF), as the cryocooler must be periodically maintained.

This disclosure provides various imaging devices for mid-wave infrared (MWIR) detection, which (among other things) may be employed in MWIR imaging systems or other systems without utilizing cryocoolers to reach the desired sensitivities and response times for the MWIR imaging systems. Various embodiments of this disclosure employ hybrid materials that integrate a two-dimensional material (2DM) for charge transport and colloidal quantum-dots (CQD) for light absorption and photocarrier generation. In some cases, the hybrid materials described here can significantly reduce detector performance-limiting mechanisms of other MWIR imagers.

FIGS. 1A and 1B illustrate an example photodetector 100 in accordance with this disclosure. More specifically, FIG. 1A illustrates a cross-sectional view of photodetector 100, and FIG. 1B illustrates an exploded perspective view of a portion of photodetector 100.

As can be seen in FIGS. 1A and 1B, photodetector 100 includes a substrate 102. In some embodiments, substrate 102 may serve as a backgate for photodetector 100 and may include silicon (Si), silicon dioxide (SiO₂), or other suitable material(s). In some embodiments, substrate 102 may represent or include at least a portion of a readout integrated circuit (ROIC). As can be seen here, substrate 102 has a surface (which in some cases may be substantially or completely planar) upon which a two-dimensional material (2DM) 104 is applied or otherwise formed. Material 104 has a first surface, which is the surface contacting substrate 102, a second surface opposite the first surface, a first end, and a second end opposite the first end. In some embodiments, material 104 may have a wide bandgap property, and may include molybdenum disulfide (MoS₂), molybdenum ditelluride (MoTe2), tungsten diselenide (WSe2), or other suitable material(s) with a wide bandgap property. In addition, in some embodiments, material 104 may include a thin film of a single element having a thickness from 1 atom to 10 atoms of the element.

A source electrode 106 is electrically coupled to the first end of material 104, and a drain electrode 108 is electrically coupled to the second end of material 104. A passivation layer 110 coats or is otherwise formed over at least a portion of the second surface of material 104, source electrode 106, and drain electrode 108. In some embodiments, passivation layer 110 may be applied to material 104, source electrode 206, and/or drain electrode 108 via atomic layer deposition (ALD) or other suitable deposition technique. Also, in some embodiments, passivation layer 110 includes at least one of boron nitride (BN) 2DM, aluminum oxide (Al₂O₃), or titanium dioxide (TiO₂). In some embodiments, passivation layer 110 covers the first and second surface of material 104. In some embodiments, passivation layer 110 may be deposited using ALD.

A CQD film is 112 is adhered to or is otherwise formed over passivation layer 110. Passivation layer 110 electrically isolates CQD film 112 from material 104, source electrode 106, and drain electrode 108. In some embodiments a passivation layer also isolates 2DM 104 from substrate 102. In some embodiments, CQD film 112 may include mercury telluride (HgTe) that has an Auger suppression property. Also, in some embodiments, CQD film 112 may have a thickness of about one micron.

Although FIGS. 1A and 1B illustrate one example of a photodetector 100, various changes may be made to FIGS. 1A and 1B. For example, while photodetector 100 is illustrated with a particular shape, photodetector 100 is not limited to any particular shape. Also, while photodetector 100 is described as including particular materials, photodetector 100 may include different materials, additional materials, etc.

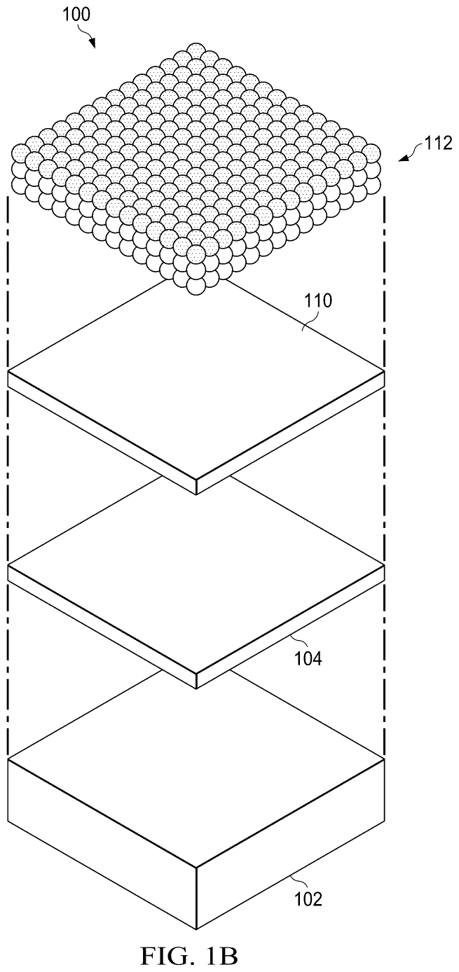

FIGS. 2A and 2B illustrate operation of an example photodetector 200 in accordance with this disclosure. More specifically, FIG. 2A illustrates a cross-sectional view of photodetector 200, while FIG. 2B illustrates an energy band diagram of the corresponding photodetector 200. In the example of FIGS. 2A and 2B, photodetector 200 should be understood to be identical or substantially similar to photodetector 100, although some elements of photodetector 100 are not shown in FIGS. 2A and 2B for clarity.

As shown in FIGS. 2A and 2B, photodetector 200 includes a substrate 202, a 2D transport channel 204 including a 2DM, a source electrode 206, a drain electrode 208, and a CQD film 212. These components may be the same as or similar to corresponding components in FIGS. 1A and 1B. In some cases, the CQD film 212 may be a HgTe CQD film (such as one being about one micron thick) that selectively absorbs MWIR light through the engineering of the CQD size and surface chemistry. For example, CQD film 212 may have an absorption coefficient of 10⁴ cm⁻¹, which is comparable to the absorption coefficient of bulk mercury cadmium telluride (HgCdTe) used in some other MWIR imagers.

During operation of photodetector 200, MWIR light 214 is absorbed by CQD film 212. Electron carriers that are photogenerated by CQD film 212 are injected 215 into the 2DM 204, driven by the band alignment as shown in FIG. 2B. The injected electron carriers generate a photocurrent 216 in the 2DM used to form 2D transport channel 204. This photocurrent may be measured between source electrode 206 and drain electrode 208. In some embodiments, the CQD film 212 can trap hole carriers with a characteristic time period known as carrier trap lifetime. To maintain the charge neutrality of the system, the photodetector 200 develops an internal photoconductive gain mechanism that amplifies the magnitude of the photocurrent 216. The photodetector 200's response time may be defined by the carrier trap lifetime, and the carrier trap lifetime may be modified using different ligand chemistry on CQD film 212. By utilizing HgTe in CQD film 212 that inherently possesses Auger suppression property and a 2DM with a wide bandgap in 2D transport channel 204, Auger generation is significantly reduced or minimized compared to other MWIR imagers. Because the CQDs in CQD film 212 are not electrically connected to 2D transport channel 204, source electrode 206, and drain electrode 208, the CQDs do not contribute to the dark current or noise in the source-to-drain circuit formed by 2D transport channel 204 including the 2DM, source electrode 206, and drain electrode 208.

Although FIGS. 2A and 2B illustrate one example of operation a photodetector 200, various changes may be made to FIGS. 2A and 2B. For example, while photodetector 200 is illustrated with a particular shape, photodetector 200 is not limited to any particular shape. Also, while photodetector 200 is described as including particular materials, photodetector 200 may include different materials, additional materials, etc. Moreover, while photodetector 200 is described to operate via electron carrier injection as illustrated in FIG. 2B, photodetector 200 can be alternatively designed to operate via hole carrier injection from CQD film 212 into 2D transport channel 204.

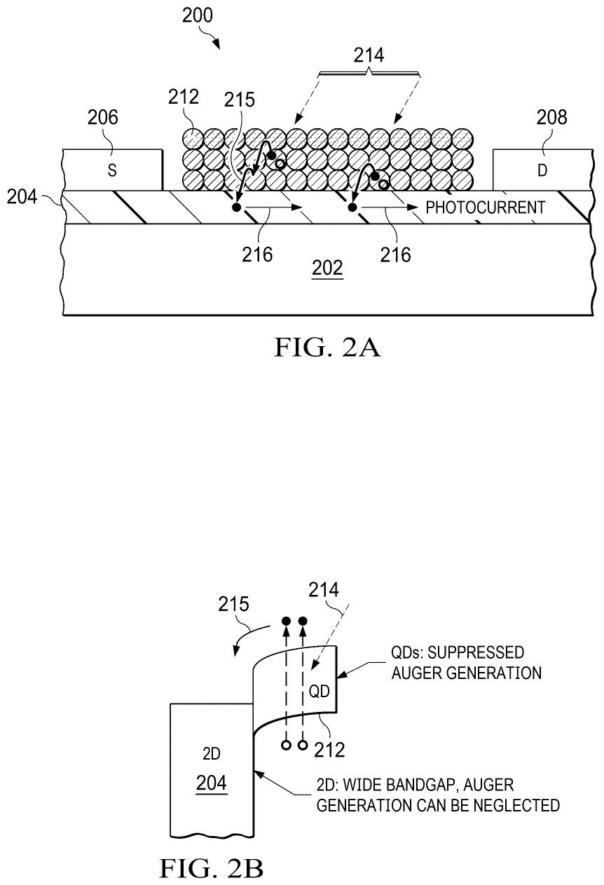

FIG. 3 illustrates an example MWIR imaging system 300 in accordance with this disclosure. As shown in FIG. 3, MWIR imaging system 300 can include a plurality of photodetectors 302 affixed to an ROIC 310 or other substrate. Each photodetector 302 may operate as a single pixel for MWIR imaging system 300. Each photodetector 302 may have the same or similar structure as photodetectors 100 and 200 shown in FIGS. 1A through 2B. MWIR imaging system 300 can absorb MWIR light and process the received light to generate thermal images based on measurements of currents induced in photodetectors 302. Unlike epitaxial semiconductors, the use of 2DM and colloidal quantum dot materials described here allows monolithic fabrication of sensors directly on top of substrates like a Si ROIC at the wafer scale.

Although FIG. 3 illustrates one example of an MWIR imaging system 300, various changes may be made to FIG. 3. For example, various components in FIG. 3 may be combined, further subdivided, replicated, omitted, or rearranged and additional components may be added according to particular needs.

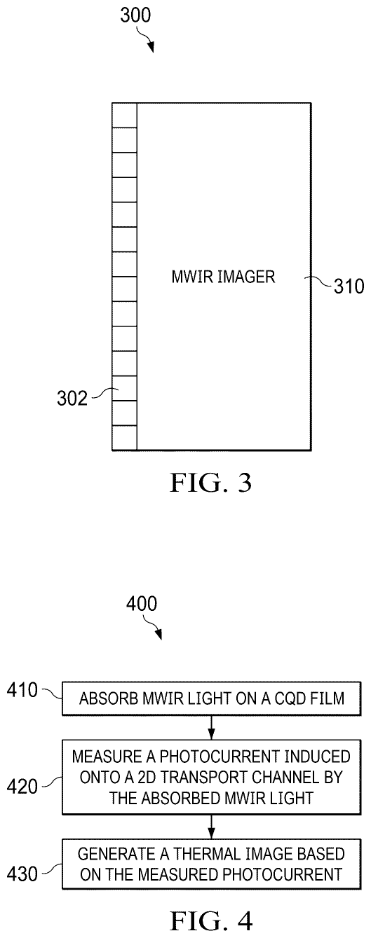

FIG. 4 illustrates an example method 400 of operating an MWIR imaging system in accordance with this disclosure. For ease of explanation, the method 400 shown in FIG. 4 may be described as involving the use of the photodetectors of FIGS. 1A through 2B. However, the method 400 shown in FIG. 4 may be involve the use of any suitable device(s) and in any suitable system(s).

As shown in FIG. 4, at step 410, an MWIR imaging system (such as MWIR imaging system 300) selectively absorbs MWIR light. For example, the MWIR light may be absorbed by a CQD film of a photodetector included in the MWIR imaging system. At step 420, the MWIR device measures a photocurrent induced onto a 2D transport channel by the absorbed MWIR light. For example, the photocarriers may be injected into a 2DM of the photodetector from the CQD film of the photodetector and give rise to the photocurrent. Note that these steps may be replicated across any number of photodetectors, such as a large number of photodetectors in a focal plane array or other structure.

At step 430, the MWIR device generates a thermal image based on the measured photocurrent. For example, the MWIR device may include at least one processor that generates thermal images based on photocurrents received from a plurality of photodetectors (such as photodetectors 302). In some embodiments, the processor(s) may be part of an ROIC (such as ROIC 310). Also, in some embodiments, each photodetector of the plurality of photodetectors may serve as a single pixel for generating the thermal images.

Although FIG. 4 illustrates one example of a method 400 of operating an MWIR imaging system, various changes may be made to FIG. 4. For example, while shown as a series of steps, various steps in FIG. 4 could overlap, occur in parallel, occur in a different order, or occur any number of times (including zero times).

It may be advantageous to set forth definitions of certain words and phrases used throughout this patent document. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. An imaging device comprising:
a substrate;
at least one two-dimensional material (2DM), the at least one 2DM having a wide bandgap property, a first surface, a second surface, a first end, and a second end opposite the first end;
a source electrode electrically coupled to the first end of the at least one 2DM;
a drain electrode electrically coupled to the second end of the at least one 2DM;
a first passivation layer over at least a portion of the at least one 2DM, the source electrode, and the drain electrode; and
a colloidal quantum-dot (CQD) film over the first passivation layer, the first passivation layer electrically isolating the CQD film from the at least one 2DM, the source electrode, and the drain electrode.

2. The imaging device of claim 1, wherein the CQD film comprises a mercury telluride (HgTe) CQD film inherently possessing an Auger suppression property.

3. The imaging device of claim 2, wherein the HgTe CQD film has a thickness of about 1 to 10 microns.

4. The imaging device of claim 1, wherein the substrate comprises at least one of:
a silicon (Si) backgate;
a silicon dioxide (SiO₂) backgate; and
a readout integrated circuit (ROIC).

5. The imaging device of claim 1, wherein the at least one 2DM comprises at least one of:
molybdenum disulfide (MoS₂);
molybdenum ditelluride (MoTe₂); and
and tungsten diselenide (WSe₂).

6. The imaging device of claim 1, wherein the at least one 2DM comprises a thin film of a single element having a thickness from 1 atom to 10 atoms of the element.

7. The imaging device of claim 1, wherein the first passivation layer comprises at least one of boron nitride (BN) 2DM, aluminum oxide (Al₂O₃), or titanium dioxide (TiO₂).

8. The imaging device of claim 1, further comprising a second passivation layer over at least a portion of the substrate isolating the substrate from the at least one 2DM.

9. A mid-wave infrared (MWIR) imaging system comprising:
a substrate;
a first passivation layer over at least a portion of the substrate; and
a plurality of photodetectors over the first passivation layer, wherein each photodetector comprises:
at least one two-dimensional material (2DM) over the first passivation layer, the at least one 2DM having a wide bandgap property, a first surface, a second surface, a first end, and a second end opposite the first end, the first passivation layer isolating the substrate from the at least one 2DM;
a source electrode electrically coupled to the first end of the at least one 2DM;
a drain electrode electrically coupled to the second end of the at least one 2DM;
a second passivation layer over at least a portion of the at least one 2DM, the source electrode, and the drain electrode; and
a colloidal quantum-dot (CQD) film over the second passivation layer, the second passivation layer electrically isolating the CQD film from the at least one 2DM, the source electrode, and the drain electrode.

10. The MWIR imaging system of claim 9, wherein, in each photodetector, the CQD film comprises a mercury telluride (HgTe) CQD film inherently possessing an Auger suppression property and having a thickness of 1 to 10 microns.

11. The MWIR imaging system of claim 9, wherein the substrate comprises at least one of:
a silicon (Si) backgate;
a silicon dioxide (SiO₂) backgate; and
a readout integrated circuit (ROIC).

12. The MWIR imaging system of claim 9, wherein, in each photodetector, the at least one 2DM comprises at least one of:
molybdenum disulfide (MeS₂);
molybdenum ditelluride (MoTe₂); and
tungsten diselenide (WSe₂).

13. The MWIR imaging system of claim 9, wherein the at least one 2DM comprises a thin film of a single element having a thickness from 1 atom to 10 atoms of the element.

14. The MWIR imaging system of claim 9, wherein, in each photodetector, at least one of the first passivation layer and the second passivation layer comprises at least one of boron nitride (BN) 2DM, aluminum oxide (Al₂O₃), or titanium dioxide (TiO₂).

15. A method comprising:
selectively absorbing, via a colloidal quantum-dot (CQD) film of a mid-wave infrared (MWIR) imaging system, MWIR light;
measuring, between a source electrode and a drain electrode of the MWIR imaging system connected by a two-dimensional (2D) transport channel, a photocurrent induced onto the 2D transport channel by the absorbed MWIR light; and
generating, by the MWIR imaging system, a thermal image based on the measured photocurrent;
wherein the 2D transport channel comprises at least one two-dimensional material (2DM) having a wide bandgap property, a first surface, a second surface, a first end, and a second end opposite the first end, the source electrode electrically coupled to the first end of the at least one 2DM, the drain electrode electrically coupled to the second end of the at least one 2DM;
wherein a first passivation layer is over at least a portion of the at least one 2DM, the source electrode, and the drain electrode; and
wherein the CQD film is over the first passivation layer such that the first passivation layer electrically isolates the CQD film from the at least one 2DM, the source electrode, and the drain electrode.

16. The method claim 15, wherein the CQD film comprises an Auger-suppressed mercury telluride (HgTe) CQD film.

17. The method of claim 15, wherein a second passivation layer exists between at least a portion of the at least one 2DM and a substrate, and the first passivation layer isolates the at least one 2DM from the substrate.

18. The method of claim 17, wherein the substrate comprises at least one of:
a silicon (Si) backgate;
a silicon dioxide (SiO₂) backgate; and
a readout integrated circuit (ROIC).

19. The method of claim 15, wherein the at least one 2DM comprises a thin film of a single element having a thickness from 1 atom to 10 atoms of the element.

20. The method of claim 15, wherein the first passivation layer comprises at least one of boron nitride (BN) 2DM, aluminum oxide (Al₂O₃), or titanium dioxide (TiO₂).
